(19) United States
(12) Patent Application Publication
(10) Pub. No.: US 2016/0212882 A1
(43) Pub. Date: Jul. 21, 2016

(54) CONTROL ELECTRONICS

(71) Applicant: ZF Friedrichshafen AG, FRIEDRICHSHAFEN (DE)

(72) Inventor: Thomas MAIER, Neunburg vorm Wald (DE)

(73) Assignee: ZF Friedrichshafen AG, FRIEDRICHSHAFEN (DE)

(21) Appl. No.: 14/995,642

(22) Filed: Jan. 14, 2016

(30) Foreign Application Priority Data
Jan. 20, 2015 (DE) 10 2015 200 868.1

(51) Int. Cl. H05K 7/20; H05K 1/18; H05K 9/00; H05K 1/02

(52) U.S. Cl. CPC H05K 7/20409; H05K 1/0201; H05K 1/181; H05K 9/002; H05K 2201/066; H05K 2201/10015

(57) ABSTRACT

A control electronics having at least one printed circuit board with electronic components is proposed, wherein at least one cooling element is assigned to the printed circuit board. The cooling element and the printed circuit board are coated with a coating material to form a media-tight unit, and the side of the cooling element facing toward the printed circuit board has at least one recess for receiving at least one electronic component of the printed circuit board that is to be protected prior to the coating thereof.

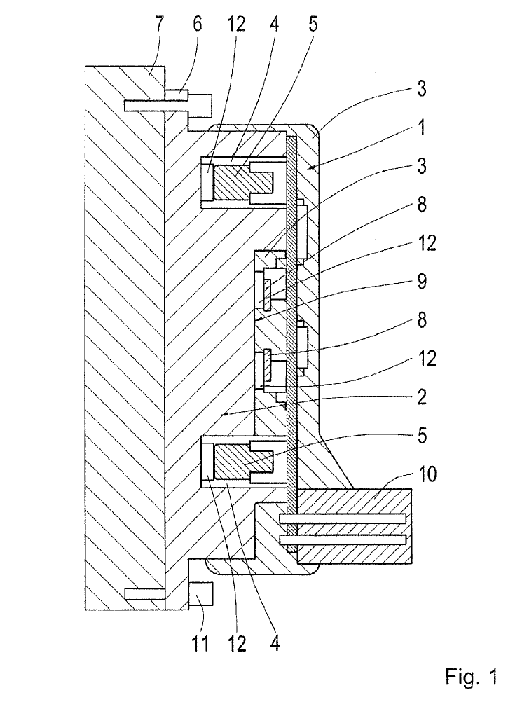

### RELATED APPLICATIONS

This application claims the priority of German Patent Application DE 10 2015 200 868.1, filed Jan. 20, 2015, which is incorporated by reference herein in its entirety.

### BACKGROUND

1. Technical Field

The present invention relates to a control electronics having at least one printed circuit board with electronic components in accordance with the type defined in greater detail in the preamble of claim 1.

2. Background Information

By way of example, a device for cooling an electrical device is known from DE 10 2013 204 029 A1. The device has a housing, in which a carrier plate, or printed circuit board, having an electrical circuitry, is disposed. The electrical circuitry is composed of electronic components. In order to discharge the resulting exhaust heat from the electronic components, numerous press-domes are in contact with the carrier plate, thus forming a cooling element, which discharges the exhaust heat from the components via the housing.

In order to protect the carrier plate from environmental effects, a housing having a complex design is necessary, which is not only expensive, but also requires a significant installation space.

### BRIEF SUMMARY OF THE INVENTION

The present invention addresses the object of proposing a media-tight control electronics, having a simple and inexpensive construction, and furthermore requiring less installation space.

This object is achieved in accordance with the invention by the features of claim 1, wherein advantageous designs can be derived from the dependent Claims, the description and the drawings.

Thus, a control electronics, or electronic control, respectively, having at least one printed circuit board with electronic components, is proposed, wherein at least one cooling element is assigned to the printed circuit board. The cooling element and the printed circuit board are coated with a coating compound, thus functioning as a media-tight unit, wherein the side of the cooling element facing toward the printed circuit board has at least one recess or suchlike for receiving at least one electronic component that is to be protected prior to the coating.

In this manner, a coated control electronics having an integrated cooling element, in the form of an aluminum injection molded element or suchlike, is provided, in which the printed circuit board, populated with electronic components, on both sides for example, and the associated aluminum cooling element, are coated and thus form a permanently integrated, no longer detachable, closed unit. The cooling element thus serves for the heat dissipation, or heat discharge to the environment, or to an element forming a heat sink, e.g. a housing wall of a transmission, a motor, a control device, or suchlike.

Because, preferably, the side, or lateral surface, of the cooling element facing the printed circuit board, at least in sections, bears against the printed circuit board in a media-tight manner, e.g. in a planar manner, undesired ingress of coating material in the recess of the cooling element is reliably prevented.

According to a first development of the present invention, the side, or lateral surface of the cooling element facing away from the printed circuit board can be designed as an attachment flange or suchlike for attaching the entire control electronics. By this means, the control electronics or suchlike can be attached in a vehicle, e.g. in a transmission housing or suchlike, in the simplest manner. By way of example, by securely screwing the cooling element to such a surface, the entire control electronics can be attached.

The proposed control electronics can preferably be used with high current applications, such as motors, actuators or suchlike, in that a connection is provided via the cooling element, for example.

A further advantage of the control electronics designed as a unit is that the cooling element also serves as an EMC shield, in order to shield the entire control electronics from electromagnetic radiation.

Aside from the high current application, the control electronics according to the invention can generally be used in vehicle engineering, as it can be used in a flexible manner due to its compact construction and its sealed construction in relation the environment.

### BRIEF DESCRIPTION OF THE DRAWING

The invention shall be explained in greater detail below, based on the drawings.

The single drawing of the invention shows a schematic view of a possible embodiment variation of a control electronics according to the invention in an exemplary manner.

### DETAILED DESCRIPTION OF THE DRAWING AND THE PRESENTLY PREFERRED EMBODIMENTS

The proposed control electronics has a printed circuit board 1 with electronic components thereon, wherein a cooling element 2 is assigned to the printed circuit board 1. The cooling element 2 and the printed circuit board 1 are coated with a coating material to form the coated region 3, and form thereby a media-tight unit. The side of the cooling element 2 facing toward the printed circuit board 1 has a recess 4, provided for receiving at least one electronic component of the printed circuit board 1 that is to be protected prior to the coating. By way of example, an electrolyte capacitor 5 is disposed without a coating in the recess 4 of the cooling element 2. The electrolyte capacitor 5 is fastened directly to the cooling element 2 in the assigned recess 4 via a thermally conductive material 12. The thermally conductive material 12 serves to not only ensure that the electrolyte capacitor 5 is cooled in an optimal manner, but also to ensure an improved protection against vibrations. A so-called SMD capacitor can preferably be provided as the electrolyte capacitor 5.

In order to be able to implement an advantageously simple attachment of the proposed control electronics device, the side of the cooling element 2 facing away from the printed circuit board 1 is provided as an attachment flange 6 for attaching the device to a housing wall, or a transmission housing wall 7, wherein the housing wall 7 forms a heat sink, and thus discharges the exhaust heat received from the printed circuit board 1 by the cooling element 2, in order to prevent overheating. The attachment flange 6 can be attached to the housing wall 7 via a screw connection 11.

The electronic components provided on the printed circuit board 1 can also be designed as components of the reverse-technology. By way of example, they can be disposed for a direct heat output on the side of the printed circuit board 1 facing the cooling element 2. As can be seen in the Figure, numerous reverse-MOSFETs 8 are provided as these types of components on the printed circuit board. The reverse-MOSFETs 8 are disposed in a recess 9 in the cooling element 2, and can conduct the resulting heat directly to the cooling element 2 via a thermally conductive material 12. The recess 9 filled with coating material 3.

In order to connect the proposed control electronics to a control device or suchlike, a control device plug 10 is coated on the coated printed circuit board 1 in a media-tight manner.

### REFERENCE SYMBOLS

1 printed circuit board

2 cooling element

3 coating region or coating material

4 recess

5 electrolyte capacitor

6 attachment flange

7 housing wall

8 reverse-MOSFET

9 recess

10 control device plug

11 screw connection

12 thermally conductive material

1. A control electronics comprising:
at least one printed circuit board with electronic components,
wherein at least one cooling element is assigned to the printed circuit board and comprises a side facing toward the printed circuit board and a side facing away from the printed circuit board,
wherein the at least one cooling element and the printed circuit board are coated with a coating material as a media-tight unit, and
wherein the side of the cooling element facing toward the printed circuit board comprises at least one recess for receiving at least one of the electronic components of the printed circuit board that is to be protected prior to the coating.

2. The control electronics of claim 1, wherein the side of the cooling element facing toward the printed circuit board bears on the printed circuit board such that it is media-tight at least in sections.

3. The control electronics of claim 1, wherein the control electrics further comprises an electrolyte capacitor disposed without a coating in the recess of the cooling element as a component that is to be protected.

4. The control electronics of claim 1, wherein the side of the cooling element facing away from the printed circuit board is provided as an attachment flange for attachment to an element forming a heat sink.

5. The control electronics of claim 1, wherein the component that is to be protected is fastened directly to the cooling element via a thermally conductive material in the recess assigned thereto.

6. The control electronics of claim 3, wherein the electrolyte capacitor is designed as an SMD capacitor.

7. The control electronics of claim 1, wherein the electronic components of the printed circuit board comprise reverse-technology for direct heat output and are disposed on the side of the printed circuit board facing the cooling element.

8. The control electronics of claim 7, wherein using_reverse-technology, at least one reverse-MOSFET of the printed circuit board is disposed such that it is coated in a recess in the cooling element, and the resulting heat can be conducted directly to the cooling element.

9. The control electronics of claim 1, wherein the cooling element comprises an EMC shield.

10. The control electronics of claim 1, wherein the control electronics further comprises a control device plug that is injection molded in a media-tight manner onto the coated printed circuit board.

11. The control electronics of claim 1, wherein the control electronics further comprises a connection to a high current application.

12. The control electronics of claim 2, wherein the control electrics further comprises an electrolyte capacitor disposed without a coating in the recess of the cooling element as a component that is to be protected.

13. The control electronics of claim 2, wherein the side of the cooling element facing away from the printed circuit board is provided as an attachment flange for attachment to an element forming a heat sink.

14. The control electronics of claim 3, wherein the side of the cooling element facing away from the printed circuit board is provided as an attachment flange for attachment to an element forming a heat sink.

15. The control electronics of claim 2, wherein the component that is to be protected is fastened directly to the cooling element via a thermally conductive material in the recess assigned thereto.

16. The control electronics of claim 4, wherein the component that is to be protected is fastened directly to the cooling element via a thermally conductive material in the recess assigned thereto.

17. The control electronics of claim 14, wherein the electrolyte capacitor is designed as an SMD capacitor.

18. The control electronics of claim 1, wherein the electronic components of the printed circuit board comprise reverse-technology for direct heat output and are disposed on the side of the printed circuit board facing the cooling element.

19. The control electronics of claim 18, wherein using reverse-technology, at least one reverse-MOSFET of the printed circuit board is disposed such that it is coated in a recess in the cooling element, and the resulting heat can be conducted directly to the cooling element.

20. The control electronics of claim 2, wherein the cooling element comprises an EMC shield.
